(19) United States
(12) Patent Application Publication
(10) Pub. No.: US 2018/0282857 A1
(43) Pub. Date: Oct. 4, 2018

(54) TRANSPARENT CONDUCTIVE FILM

(71) Applicant: NITTO DENKO CORPORATION, Ibaraki-shi, Osaka (JP)

(72) Inventors: Daiki Kato, Ibaraki-shi (JP); Nozomi Fujino, Ibaraki-shi (JP); Tomotake Nashiki, Ibaraki-shi (JP)

(73) Assignee: NITTO DENKO CORPORATION, Ibaraki-shi, Osaka (JP)

(21) Appl. No.: 15/575,686

(22) PCT Filed: Oct. 30, 2015
(86) PCT No.: PCT/JP2015/080694

§ 371 Date: Nov. 20, 2017

(30) Foreign Application Priority Data
May 27, 2015 (JP) 2015-107003
Oct. 15, 2015 (JP) 2015-203740

(51) Int. Cl. C23C 14/08; C23C 14/10

(52) U.S. Cl. CPC C23C 14/086; C23C 14/34; C23C 14/10

(57) ABSTRACT

A transparent conductive film includes a transparent substrate film, a hard coat layer, an optical adjustment layer, and a transparent conductor layer, in which the hard coat layer, the optical adjustment layer, and the transparent conductor layer are laminated on the transparent substrate film in this order. The hard coat layer has a thickness of 250 nm to 2,000 nm, and the thickness of the optical adjustment layer is 2% to 10% of the thickness of the hard coat layer. Crystallization of the transparent conductor layer is completed by heating at, for example, 140° C. for 30 minutes.

### BACKGROUND OF THE INVENTION

### Field of the Invention

The present invention relates to a transparent conductive film.

### Description of the Related Art

A transparent conductive film where a transparent conductor layer is formed on a transparent substrate film has widely been used for an apparatus such as a touch panel. When a transparent conductive film is used for a touch panel, wiring patterns are formed by etching the transparent conductor layer by use of photolithography. In recent years, as wiring patterns of a transparent conductor layer becomes miniaturized, there has been a higher possibility of wiring being short due to a small scratch. Therefore, it is known that a hard coat layer is arranged between a substrate film and a transparent conductor layer to enhance scratch resistance of the transparent conductive film (Japanese Patent No. 4214063 B2).

On the other hand, it is known that an optical adjustment layer (IM layer: Index Matching Layer) is arranged between a transparent conductor layer and a hard coat layer to make wiring patterns hard to be visible (Japanese Patent No. 5425351 B1). The difference between a portion with wiring patterns and a portion without wiring patterns becomes smaller by the optical adjustment layer. This makes the wiring patterns hard to be visible.

While crystallization of a transparent conductor layer is necessary to lower the resistance value of the transparent conductor layer in a transparent conductive film, gas contained (e.g. moisture) in a substrate film is released, which may lead to inhibit the crystallization of the transparent conductor layer due to the gas (outgas). To prevent it, it is known to use an optical adjustment layer with gas barrier properties (Japanese Patent No. 5245893 B2).

In recent years, however, miniaturization of wiring patterns formed in a transparent conductor layer has highly been developed. It has turned out that conventional transparent conductive films have insufficient scratch resistance. Additionally, in recent years, a reduction of time for crystallization of the transparent conductor layer has strongly been demanded to improve productivity. In conventional transparent conductive films, crystallization speed has been delayed by the inhibition of crystallization of transparent conductor layers, thus leading to impossibility of responding to crystallization in a short period of time required at the time of mass production.

### PRIOR ART DOCUMENTS

### Patent Documents

Patent document 1: Japanese Patent No. 4214063 B2

Patent document 2: Japanese Patent No. 5425351 B1

Patent document 3: Japanese Patent No. 5245893 B2

### SUMMARY OF THE INVENTION

It is an object of the present invention to achieve a transparent conductive film having high scratch resistance, in which crystallization of a transparent conductor layer can be completed in a short period of time.

The present inventors have resultantly found out that crystallization speed of a transparent conductor layer becomes faster with increasing of scratch resistance of a transparent conductive film by appropriately balancing the thickness of a hard coat layer and the thickness of an optical adjustment layer, and crystallization is completed in a short period of time. As a result, the transparent conductive film of the present invention has been completed.

The summary of the present invention is described as below.

In a first preferred aspect, there is provided a transparent conductive film according to the present invention which includes: a transparent substrate film; a hard coat layer; an optical adjustment layer; and a transparent conductor layer, in which at least the hard coat layer, the optical adjustment layer, and the transparent conductor layer are laminated on the transparent substrate film in this order (FIG. 1). The transparent conductor layer includes indium. The hard coat layer has a thickness of 250 nm to 2,000 nm. The thickness of the optical adjustment layer is 2% to 10% of the thickness of the hard coat layer.

In a second preferred aspect of the transparent conductive film according to the present invention, the optical adjustment layer includes a metal oxide.

In a third preferred aspect of the transparent conductive film according to the present invention, the metal oxide includes silicon dioxide (SiO₂).

In a fourth preferred aspect of the transparent conductive film according to the present invention, the hard coat layer includes any one of zirconium oxide ZrO₂, silicon dioxide SiO₂, titanium oxide TiO₂, tin oxide SnO₂, and aluminum oxide Al₂O₃ or at least two kinds of these inorganic fine particles.

In a fifth preferred aspect of the transparent conductive film according to the present invention, the hard coat layer has a refractive index of 1.60 to 1.70.

In a sixth preferred aspect, the transparent conductive film according to the present invention further includes an antistripping layer formed between the hard coat layer and the optical adjustment layer (FIG. 2).

In a seventh preferred aspect of the transparent conductive film according to the present invention, the antistripping layer includes a non-stoichiometric inorganic compound.

In an eighth preferred aspect of the transparent conductive film according to the present invention, the antistripping layer includes silicon atoms.

In a ninth preferred aspect of the transparent conductive film according to the present invention, the antistripping layer includes a silicon compound.

In a tenth preferred aspect of the transparent conductive film according to the present invention, the antistripping layer includes a silicon oxide.

In an eleventh preferred aspect of the transparent conductive film according to the present invention, the antistripping layer has an area, in which bond energy of a Si2p bond is 98.0 eV or more to less than 103.0 eV.

In a twelfth preferred aspect of the transparent conductive film according to the present invention, the antistripping layer has a thickness of 1.5 nm to 8 nm.

In a thirteenth preferred aspect, the transparent conductive film according to the present invention further includes a functional layer formed on the other main surface of the substrate film opposite to the transparent conductor layer (FIG. 3).

In a fourteenth preferred aspect of the transparent conductive film according to the present invention, the functional layer is composed of an anti-blocking hard coat layer.

### Advantages of the Invention

According to the present invention, a transparent conductive film having high scratch resistance, in which crystallization of a transparent conductor layer is completed in a short period of time, has been achieved. Crystallization of the transparent conductor layer is completed by heating at, for example, 140° C. for 30 minutes.

### BRIEF DESCRIPTION OF THE DRAWINGS

FIG. 1 is a schematic view of a first embodiment of a transparent conductive film of the present invention;

FIG. 2 is a schematic view of a second embodiment of the transparent conductive film of the present invention; and

FIG. 3 is a schematic view of a third embodiment of the transparent conductive film of the present invention.

### DESCRIPTION OF THE PREFERRED EMBODIMENTS

### [Transparent Conductive Film]

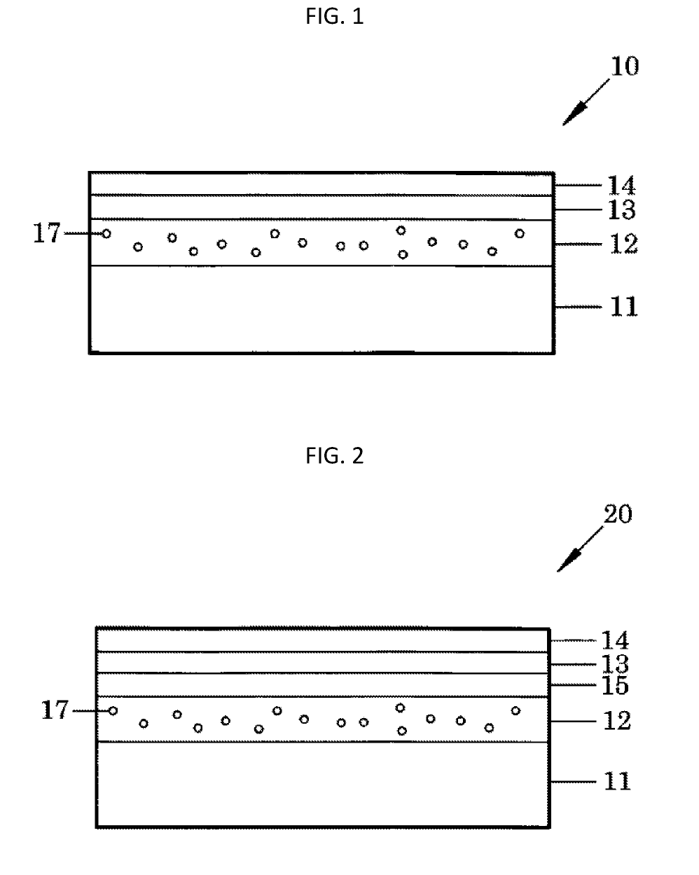

FIG. 1 is a schematic view of a first embodiment of a transparent conductive film 10 of the present invention. In the transparent conductive film 10, a hard coat layer 12, an optical adjustment layer 13, and a transparent conductor layer 14 are laminated on a transparent substrate film 11 in this order. The hard coat layer 12 has a thickness of 250 nm to 2,000 nm. The thickness of the optical adjustment layer 13 is 2% to 10% of the thickness of the hard coat layer 12. Crystallization of the transparent conductor layer 14 is completed by heating at, for example, 140° C. for 30 minutes.

As criteria for judging the completion of crystallization of the transparent conductor layer 14, the degree of variations of resistance values relative to heating time of the transparent conductor layer 14 is herein adopted. For instance, in the case where the transparent conductor layer 14 has a surface resistance value after heating at 140° C. for 30 minutes, which is 1.1 time or less as large as the surface resistance value after heating at 140° C. for 90 minutes, crystallization is to be judged as completed.

FIG. 2 is a schematic view of a second embodiment of a transparent conductive film 20 of the present invention. The difference between the transparent conductive film 10 in FIG. 1 and the transparent conductive film 20 in FIG. 2 is that the transparent conductive film 20 further includes an antistripping layer 15 formed between a hard coat layer 12 and an optical adjustment layer 13. The antistripping layer 15 has a function of improving adhesion between the hard coat layer 12 and the optical adjustment layer 13. As a result, the antistripping layer 15 improves adhesion between a substrate film 11 and the optical adjustment layer 13. The antistripping layer 15 will be described in detail later.

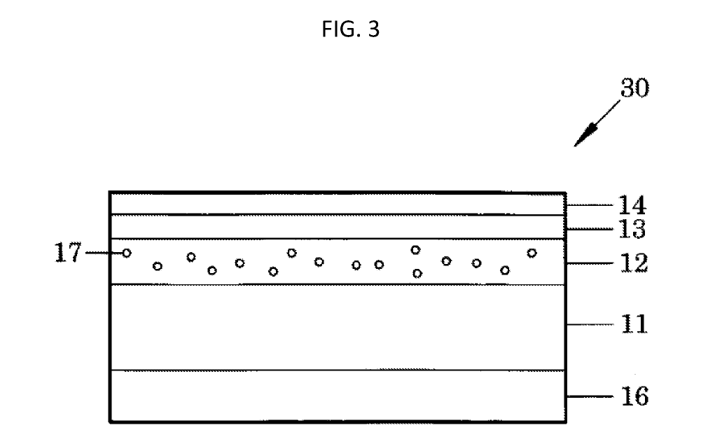

FIG. 3 is a schematic view of a third embodiment of a transparent conductive film 30 of the present invention. The difference between the transparent conductive film 10 in FIG. 1 and the transparent conductive film 30 in FIG. 3 is that the transparent conductive film 30 further includes a functional layer 16 formed on a lower surface of a substrate film 11. The functional layer 16 will be described in detail later.

### [Substrate Film]

The substrate film 11 is made from a plastic film, such as a polyester film composed of polyethylene terephthalate (PET), polybutylene terephthalate, and polyethylene naphthalate (PEN), a polyethylene film, a polypropylene film, a cellophane film, a diacetylcellulose film, a triacetyle cellulose film, an acetylcellulosebutylate film, a polyvinyl chloride film, a polyvinylidene chloride film, a polyvinyl alcohol film, an ethylene-vinyl acetate copolymer film, a polystyrene film, a polycarbonate film, a polymethyl pentene film, a polysulfone film, a polyether ether ketone film, a polyether sulfone film, a polyether imide film, a polyimide film, a fluorine resin film, a polyamide film, an acrylic resin film, a norbornene-based resin film, and a cycloolefin resin film. While the material of the substrate film 11 is not limited to these, polyethylene terephthalate which is superior in transparency, heat resistance, and mechanical properties is particularly preferable.

While the substrate film 11 preferably has a thickness of 20 μM or more to 300 μm or less, the thickness of the film substrate is not limited to this. In the case where the thickness of the substrate film 11 is less than 20 μM, it may be difficult to handle the substrate film 11. In the case where the thickness of the substrate film 11 is over 300 μm, the transparent conductive films 10, 20, 30 become too thick when each mounted on a touch panel or the like, which may cause a problem.

The substrate film 11 preferably has a thermal shrinkage of −0.5% to +1.5%, more preferably −0.5% to +1.0%, furthermore preferably −0.5% to +0.7%, the most preferably −0.5% to +0.5% in its main surface. When the thermal shrinkage of the substrate film 11 is over 1.5%, for instance, like the time when the transparent conductor layer 14 is heated and crystallized, the substrate film 11 greatly shrinks by addition of heat to the substrate film 11 and excessive compression stress is applied on each layer. This may cause each layer to be easily peeled off. The thermal shrinkages of the transparent conductive films 10, 20, 30 are substantially the same as the thermal shrinkage of the substrate film 11.

When the substrate film 11 is conveyed by a roll-to-roll type sputtering device, to prevent the thermal shrinkage of the substrate film 11 from excessively increasing, a layer forming roll preferably has a surface temperature of −20° C. to +100° C., more preferably −20° C. to +50° C., furthermore preferably −20° C. to 0° C. when sputtering. In general, when the substrate film 11 is conveyed by pulling while heating the substrate film 11 by use of the layer forming roll, the thermal shrinkage of the substrate film 11 tends to be higher. It is preferable to perform sputtering while cooling the substrate film 11 by use of the layer forming roll so that the thermal shrinkage of the substrate film 11 may not be higher. [Hard coat layer]

The hard coat layer 12 has a function (scratch resistance) to prevent wiring patterns formed on the transparent conductor layer 14 from being disconnected and shorted due to scratches that appear on the transparent conductive film 10. The hard coat layer 12 may contain inorganic fine particles 17. The inorganic fine particles 17 are dispersed on the hard coat layer 12. As a result, it is possible to adjust the refractive index of the hard coat layer 12 and improve the transmittance of the transparent conductive film 10. Alternatively, it is possible to bring the reflection hue of the transparent conductive film 10 close to be neutral (an achromatic color).

The hard coat layer 12 includes, for instance, an organic resin, preferably an organic resin and the inorganic fine particles 17, more preferably is substantially composed of the organic resin and the inorganic fine particles 17 only. A typical example of the organic resin includes a hardening resin. Examples of the hardening resin include an active energy ray hardening resin which is cured by irradiating active energy rays (such as ultraviolet rays, electron beams) and a thermosetting resin cured by heating, preferably an active energy ray hardening resin.

An example of the active energy ray hardening resin includes polymer having a functional group with e.g. a polymerizable carbon-carbon double bond. Examples of such a functional group include a vinyl group and a (meth)acryloyl group (a methacryloyl group and/or an acryloyl group). An Example of the active energy ray hardening resin includes, for example, a (meth) acrylic resin with a functional group on its side chain (an acrylic resin and/or a methacryl resin). These resins can be used alone and can be used in combination of at least two kinds of these resins.

The material and size of the inorganic fine particles 17 contained in the hard coat layer 12 are not particularly limited. Examples of the material of the inorganic fine particles 17 include fine particles, such as zirconium oxide ZrO₂, silicon dioxide SiO₂, titanium oxide TiO₂, tin oxide SnO₂, and aluminum oxide Al₂O₃. At least two kinds of such fine particles may be contained in the hard coat layer 12. The particle size (average particle) of each of the inorganic fine particles 17 is preferably 10 nm to 80 nm, more preferably 20 nm to 40 nm. When the particle size is less than 10 nm, particles may not uniformly disperse in the resin. When the particle size is over 80 nm, the surface resistance value of the transparent conductor layer 14 may rise due to irregularities caused on the surface. While the hard coat layer 12 can be formed by coating and drying an organic resin (e.g. an acrylic resin) containing, for example, the inorganic fine particles 17 on the substrate film 11, the material and the production method thereof are not limited to this.

The content ratio of the inorganic fine particles 17 is, for example, 5 weight parts or more to 100 weight parts or less relative to 100 weight parts of resin, preferably 10 weight parts or more to 65 weight parts or less. The refractive index of the resin (the hard coat layer 12) containing the inorganic fine particles 17 can be adjusted by adjusting the content ratio of the inorganic fine particles 17.

The hard coat layer 12 preferably has a thickness of 250 nm to 2,000 nm. When the thickness of the hard coat layer 12 is less than 250 nm, scratch resistance may be insufficient. An organic solvent or a water solvent is used for the hard coat layer 12 and thus the hard coat layer 12 contains a large amount of gas. When the thickness of the hard coat layer 12 is over 2,000 nm, the amount of gas contained (typically, moisture) in the hard coat layer 12 is excessive. This may inhibit crystallization of the transparent conductor layer 14 due to difficulties in blocking gas (outgas) released from the hard coat layer 12 with the optical adjustment layer 13.

While the refractive index of the hard coat layer 12 is not particularly limited, the refractive index is preferably 1.60 to 1.70. When the refractive index of the hard coat layer 12 departs from this range (1.60 to 1.70), the wiring patterns (not shown) formed on the transparent conductor layer 14 may be easily visible. The refractive index of the hard coat layer 12 is measured by an Abbe refractometer.

The hard coat layer is coated by, for instance, a fountain coating method, a die coating method, a spin coating method, a spray coating method, a gravure coating method, a roll coating method, and a bar-coating method. Specifically, first, a diluent in which a resin component is diluted by a solvent, is adjusted and then the substrate film is coated with the diluent and is dried to form a hard coat layer.

Examples of the solvent include an organic solvent and a water solvent, preferably an organic solvent. Examples of the organic solvent include an alcohol-based solvent, such as ethanol and isopropyl alcohol, a ketone-based solvent, such as acetone, methyl ethyl ketone (MEK), methyl isobutyl ketone (MIBK), an ester-based solvent, such as ethyl acetate and butyl acetate, and an aromatic compound, such as toluene and xylene, preferably a mixed solvent of these is used. The resin component is used after diluted by the solvent so that the solid content concentration may be e.g. 0.5 weight parts or more to 5.0 weight parts or less.

The drying temperature of the diluent coated on the substrate film 11 is, for example, 60° C. or more to 250° C. or less, more preferably 80° C. or more to 200° C. or less. When the drying temperature is too low, the solvent remains. This may lead to deterioration of the layer quality of the transparent conductor layer. When the drying temperature is too high, wrinkles are created on the film. This may cause a disadvantage in appearance. The drying time is, for example, one minute or more to 60 minutes or less, more preferably two minutes or more to 30 minutes or less. When the drying time is too short, the solvent remains. This may lead to deterioration of the layer quality of the transparent conductor layer. When the drying time is too long, wrinkles are created on the film. This may cause a disadvantage in appearance.

### [Optical Adjustment Layer]

The optical adjustment layer 13 is used to adjust the refractive index of each of the transparent conductive films 10, 20, 30. Optical characteristics (e.g. reflection characteristics) of the transparent conductive films 10, 20, 30 can be optimized by the optical adjustment layer 13. The difference of the refractive index between the pattern portion and the non-pattern portion of the transparent conductor layer 14 is minimized by forming the optical adjustment layer 13. This makes wiring patterns of the transparent conductor layer 14 hard to be visible (the wiring patterns are preferably invisible).

The optical adjustment layer 13 is formed by a drying method (a drying process). The optical adjustment layer 13 formed by the drying method has high hardness and scratch resistance of the transparent conductive film 10 is higher in combination with the function of the hard coat layer 12. The optical adjustment layer 13 formed by the drying method has gas barrier properties. As a result, it is possible to prevent the layer of the transparent conductor layer 14 from being crystallization-inhibited and being deteriorated by outgas by preventing outgas generated from the substrate film 11 and the hard coat layer 12 from entering the transparent conductor layer 14.

The constituent material of the optical adjustment layer 13 is not particularly limited, and examples thereof include metal oxides, such as silicon monooxide (Si0), silicon dioxide (SiO₂), silicon suboxide (SiOx: x is not smaller than 1 and less than 2), aluminum oxide (Al₂O₃), zirconium oxide (ZrO₂), and titanium oxide (TiO₂). Above all, silicon dioxide (SiO₂) (this is usually referred to as silicon oxide or silica) is the most preferable as a constituent material for the optical adjustment layer 13. The optical adjustment layer 13 may also be a single metal oxide layer. The optical adjustment layer 13 may also be a laminate of metal oxide layers where a plurality of metal oxide layers having different metal atoms are laminated.

The thickness of the optical adjustment layer 13 is preferably 2% to 10% of the thickness of the hard coat layer 12. When the thickness of the optical adjustment layer 13 is less than 2% of the thickness of the hard coat layer 12, gas barrier properties of the optical adjustment layer 13 may be insufficient. When the gas barrier properties of the optical adjustment layer 13 is insufficient, crystallization of the transparent conductor layer 14 may be not completed in a short period of time. When the thickness of the optical adjustment layer 13 is over 10% of the hard coat layer 12, flexibility resistance of the transparent conductive films 10, 20, 30 may be deteriorated. In addition, productivity of the optical adjustment layer 13 may be lowered.

The reason why the thickness of the optical adjustment layer 13 is linked to the thickness of the hard coat layer 12 is that as the thickness of the hard coat layer 12 is thicker, the amount of outgas released from the hard coat layer 12 becomes larger. As a result, the thickness of the optical adjustment layer 13 for blocking outgas also needs to be thickened. Conversely, when the thickness of the hard coat layer 12 is thin, outgas released from the hard coat layer 12 becomes less. This allows the thickness of the optical adjustment layer 13 for blocking outgas to be thin.

While the optical adjustment layer 13 is deposited by the sputtering method, the vapor-deposition method, and Chemical Vapor Deposition method, the production method thereof is not limited to these methods. The optical adjustment layer 13 is deposited particularly preferably by the sputtering method. Even in the drying method, it is typically possible to stably obtain a particularly dense layer by the sputtering method. As a result, the optical adjustment layer 13 formed by the sputtering method has high scratch resistance. In general, the layer to be formed has a density higher in the sputtering method than, for instance, the vacuum deposition method, which makes it possible to obtain the optical adjustment layer 13 superior in gas barrier properties.

Pressure of (typically, argon gas) at the time when the optical adjustment layer 13 is deposited is preferably 0.09 Pa to 0.5 Pa, more preferably 0.09 Pa to 0.3 Pa. A denser layer can be formed by making the pressure of the sputtering gas in the aforementioned range. As a result, it becomes easy to obtain preferable scratch resistance and gas barrier properties. When the pressure of the sputtering gas is over 0.5 Pa, it may be impossible to obtain a dense layer. When the pressure of the sputtering gas is less than 0.09 Pa, electric discharge becomes unstable, which may result in formation of voids on the layer.

When the optical adjustment layer 13 is deposited by the sputtering method, effective deposition is possible by use of a reactive sputtering method. For instance, a silicon dioxide (SiO₂) layer having high scratch resistance and high gas barrier properties can be obtained by use of silicon (Si) as a sputtering target, introducing argon gas as sputtering gas and oxygen gas of 10 pressure % to 50 pressure % as reactive gas relative to the argon gas.

When the optical adjustment layer 13 is deposited by the sputtering method, a power density to be applied to the target is preferably 1.0 W/cm² to 6.0 W/cm². When the power density is over 6.0 W/cm², the optical adjustment layer 13 has greater surface roughness (e.g. arithmetic surface average roughness Ra), which may result in an increase in surface resistance of the transparent conductor layer 14. When the power density is less than 1.0 W/cm², the deposition rate becomes slower, which may result in difficulty in maintaining productivity of the optical adjustment layer 13.

### [Transparent Conductor Layer]

The transparent conductor layer 14 is a thin layer composed essentially of a metal conductive oxide (e.g. indium oxide) or a transparent thin layer composed essentially of a composite metal oxide including main metal (e.g. indium) and at least one kind of impurity metal (e.g. tin). The configuration and material of the transparent conductor layer 14 are not particularly limited as long as the transparent conductor layer 14 has optical transparency in a visible light region and conductivity.

For example, while indium oxide, indium tin oxide (ITO), indium zinc oxide (IZO), indium gallium zinc oxide (IGZO) are used as the transparent conductor layer 14, ITO is preferable from a viewpoint of low resistivity and transmission hue.

The transparent conductor layer 14 may further contain impurity metal atoms such as titanium Ti, magnesium Mg, aluminum Al, gold Au, silver Ag or copper Cu. While the transparent conductor layer 14 is formed by the sputtering method and the vapor-deposition method, the production method thereof is not limited to these methods.

The amount of impurity metal atoms (e.g. tin Sn) contained in the transparent conductor layer 14 is preferably 0.5 weight % to 15 weight %, more preferably 3 weight % to 15 weight %, furthermore preferably 5 weight % to 13 weight % relative to the total amount of indium oxide (In₂O₃) and the impurity metal atoms (e.g. tin Sn). When tin oxide is less than 0.5 weight %, the surface resistance value of the transparent conductor layer 14 may become higher. When tin oxide is over 15 weight %, uniformity of the surface resistance value in the surface of the transparent conductor layer 14 may be lost.

The transparent conductor layer 14 (e.g. indium tin oxide layer) formed at a low temperature is amorphous and can be converted from being amorphous into being crystalline by heat treatment. The transparent conductor layer 14 has a lower surface resistance value by being converted into crystalline qualities. Conditions for heat treatment at the time of converting the transparent conductor layer 14 into being crystalline are preferably heating at 140° C. for 30 minutes or shorter from a viewpoint of productivity.

The thickness of the hard coat layer 12 is 250 nm to 2,000 nm, which is thin and outgas released from the hard coat layer 12 is in a small amount. In addition, the thickness of the optical adjustment layer 13 is 2% to 10% of the thickness of the hard coat layer 12 and thus the optical adjustment layer 13 has high gas barrier properties. As a result, crystallization of the transparent conductor layer 14 is not easily affected by outgas released from the substrate film 11 and the hard coat layer 12. This enables the completion of the crystallization by heating at 140° C. for 30 minutes or shorter.

The transparent conductor layer 14 preferably has an arithmetic surface roughness Ra of 0.1 nm or more to 1.6 nm or less. When the arithmetic surface roughness Ra is over 1.6 nm, the surface resistance value of the transparent conductor layer 14 may rise. When the arithmetic surface roughness Ra is less than 0.1 nm, etching failure may occur due to a decrease in adhesion between a photoresist and the transparent conductor layer 14 when forming wires by patterning the transparent conductor layer 14 with photolithography.

The transparent conductor layer 14 preferably has a thickness of 15 nm or more to 40 nm or less, more preferably 15 nm or more to 35 nm or less. The transparent conductive films 10, 20, 30 are preferably applicable to touch panels by making the thickness of each of the transparent conductor layer 14 in the aforementioned range. When the thickness of the transparent conductor layer 14 is less than 15 nm, the surface resistance value of the transparent conductor layer 14 may rise. When the thickness of the transparent conductor layer 14 is over 40 nm, the light transmittance of the transparent conductive films 10, 20, 30 may be lowered and cracks may appear on the transparent conductor layer 14 due to a rise in internal stress. The transparent conductor layer 14 may be a laminated layer where at least two layers of transparent conductor layers are laminated.

### [Antistripping Layer]

Like the transparent conductive film 20 in FIG. 2, the antistripping layer 15 may be formed between the hard coat layer 12 and the optical adjustment layer 13. Adhesion between the hard coat layer 12 and the optical adjustment layer 13 can be enhanced by the formation of the antistripping layer 15 between the hard coat layer 12 and the optical adjustment layer 13. As a result, adhesion between the substrate film 11 and the optical adjustment layer 13 can be enhanced.

The antistripping layer 15 contains inorganic atoms and is preferably composed of an inorganic substance such as an inorganic simple body and an inorganic compound and is more preferably composed of an inorganic compound. Examples of the inorganic atoms contained in the antistripping layer 15 include metal atoms, such as silicon (Si), niobium (Nb), palladium (Pd), titanium (Ti), indium (In), tin (Sn), cadmium (Cd), zinc (Zn), antimony (Sb), aluminum (Al), tungsten (W), molybdenum (Mo), chrome (Cr), tantalum (Ta), nickel (Ni), platinum (Pt), gold (Au), silver (Ag) or copper (Cu), preferably silicon (Si).

Specifically, the antistripping layer 15 is composed of an elemental silicon or a silicon compound and is preferably composed of a silicon compound from a viewpoint of transparency. In addition, the inorganic compound is preferably composed of a non-stoichiometric inorganic compound.

Examples of the non-stoichiometric inorganic compound include inorganic nitride, such as silicon nitride (e.g. SiNx, 0.1≤x<1.3), inorganic carbide, such as silicon carbide (e.g. SiCx, 0.1≤x<1.0), inorganic oxide, such as silicon oxide (e.g. SiOx, 0.1≤x<2.0). The non-stoichiometric inorganic compound is preferably composed of a silicon oxide (e.g. SiOx, 0.1≤x<2.0). Each of these inorganic compounds may be a single composition or a mixture of a plurality of compositions.

In the case where the antistripping layer 15 is composed of, for example, a non-stoichiometric silicon compound, the antistripping function can be improved further by adjusting bond energy of a Si2p orbit to a suitable range than the case in which the antistripping layer 15 is stoichiometric (e.g. silicon dioxide SiO₂).

An element for constituting the antistripping layer 15 is preferably the same kind of metal as the metal of the metal oxide contained in the optical adjustment layer 13 or a different kind of metal. Adhesion between the antistripping layer 15 and the optical adjustment layer 13 can further be improved when the element for constituting the antistripping layer 15 is the same kind of metal (silicon Si relative to silicon dioxide Sio₂) as the metal of the metal oxide (e.g. silicon dioxide SiO₂) contained in the optical adjustment layer 13. Accordingly, the element for constituting the antistripping layer 15 is more preferably the same kind of metal as the metal of the metal oxide.

The antistripping layer 15 preferably has a thickness of 1.5 nm to 8 nm. Both excellent optical characteristics and high adhesion can be obtained by having a thickness of 1.5 nm to 8 nm in the antistripping layer 15. When the antistripping layer 15 has a thickness of less than 1.5 nm, there is a possibility of insufficient improvement of adhesion by use of the antistripping layer 15. When the antistripping layer 15 has a thickness of over 8 nm, reflection and absorption of light is caused by free electrons in the antistripping layer 15, resulting in a lower light transmittance of the transparent conductive film 20. This makes a display such as a liquid crystal display located under the transparent conductive film 20 hard to see.

While the antistripping layer 15 is formed by a sputtering method, a vapor-deposition method or a Chemical Vapor Deposition method, the production method thereof is not limited to these methods. However, the sputtering method is preferable in view of denseness of a layer and productivity. In the case where the antistripping layer 15 is deposited by the sputtering method, the antistripping layer 15 is obtainable, for example, by applying power having e.g. a power density of 1.0 W/cm² and sputtering a metal target under a vacuum atmosphere of 0.2 Pa to 0.5 Pa where argon has been introduced. The antistripping layer 15 is preferably deposited without the introduction of reaction gas such as oxygen in the case.

The thickness of the antistripping layer 15 can be measured by use of an image of a Transmission Electron Microscope (TEM), in which a cross section of the transparent conductive film 20 has been taken. Differences of contrast arise between the antistripping layer 15 and the optical adjustment layer 13 in the cross-section TEM image. When the antistripping layer 15 is thin and an element of the antistripping layer 15 and an element of the optical adjustment layer 13 are the same, the differences of contrast are sometimes unclear.

Even in such a case, when a depth profile of bond energy of the element is performed by an X-ray Photoelectron Spectroscopy (XPS, another name: ESCA: Electron Spectroscopy for Chemical Analysis) by use of sputtering etching by argon gas, differences in bond energy arise between the antistripping layer 15 and the optical adjustment layer 13. This enables confirmation of the existence of the antistripping layer 15.

When the antistripping layer 15 contains silicon atoms (Si), bond energy of the Si2p orbit obtained by the XPS in the antistripping layer 15 is e.g. 98.0 eV or more, preferably 99.0 eV or more, more preferably 100.0 eV or more, more preferably 102.0 eV or more, in addition, e.g. less than 104.0 eV, preferably less than 103.0 eV, more preferably 102.0 eV or less. Alternatively, the bond energy is, for example, less than 104.0 eV, preferably less than 103.0 eV, more preferably less than 102.8 eV or less. Selection of the antistripping layer 15 in which bond energy of the Si2p orbit is in the aforementioned range makes adhesion of the antistripping layer 15 enhanced more. In particular, when the bond energy in the antistripping layer 15 is 99.0 eV or more to less than 103.0 eV, the antistripping layer 15 contains a non-stoichiometric silicon compound. As a result, it is possible to more surely improve the adhesion while maintaining the excellent light transmittance. Further, distribution of the bond energy in a thickness direction inside the antistripping layer 15 may have a gradient which gradually becomes higher toward a side of the optical adjustment layer 13 from a side of the antistripping layer 15.

In measurement of bond energy, when a layer such as the optical adjustment layer 13 is formed on the antistripping layer 15, a depth profile (a measurement pitch is set for each 1 nm in silicon dioxide SiO₂ equivalent) is measured by the XPS. When bond energy is continuously changed, a bond energy value from a terminal portion of the side of the substrate film 11 of the antistripping layer 15 to a point of the upper side of 1 nm or more (preferably a point of the upper side of 1 nm) is adopted. In addition, when the inorganic atoms that constitute the antistripping layer 15 are identical to the inorganic atoms that constitute the optical adjustment layer 13 (e.g. when the antistripping layer 15 is a silicon (Si) compound and the optical adjustment layer 13 is silicon dioxide SiO₂), a depth position that the element ratio of inorganic atoms (Si) is a half value relative to a peak value is a terminal portion of the antistripping layer 15.

### [Functional Layer]

As shown in FIG. 3, a functional layer 16 may be formed on a side of the substrate layer 11 opposite to the transparent conductor layer 14. While the functional layer 16 is not particularly limited, examples of the functional layer include an anti-blocking hard coat layer and an optical adjustment layer. The anti-blocking hard coat layer prevents the adjacent transparent conductive film 30 in a radial direction from being attached (blocking) when the long transparent conductive film 30 is wound in a roll shape. The optical adjustment layer 13 improves the transmittance of the transparent conductive film 30, alternatively the optical adjustment layer 13 makes a pattern portion hard to be visible when the transparent conductor layer 14 is patterned.

### Examples and Comparative Examples

While concrete embodiments of the transparent conductive film of the present invention will now be described, comparing Examples and Comparative Examples, it is understood that the present invention is not limited to these embodiments.

### Example 1

FIG. 1 shows a layer configuration of Example 1. A substrate film 11 is a polyethylene terephthalate (PET) film with a thickness of 100 μm. A hard coat layer 12 is an acrylic resin layer with a thickness of 700 nm. The hard coat layer 12 includes zirconium oxide (ZrO₂) fine particles (inorganic fine particles 17) with an average particle size of 20 nm. An optical adjustment layer 13 is a silicon dioxide (SiO₂) layer with a thickness of 15 nm. The thickness of the optical adjustment layer 13 is 2.1% of the thickness of the hard coat layer 12. A transparent conductor layer 14 is an indium tin oxide (ITO) layer with a thickness of 20 nm. The weight ratio of tin to the total amount of indium oxide and tin contained in the transparent conductor layer 14 is 10%.

### [Formation of Hard Coat Layer]

An ultraviolet (UV)-hardening resin composition including an acrylic resin and zirconium oxide (ZrO₂) fine particles (average particle size: 20 nm) was diluted with methyl isobutyl ketone (MIBK) to make the solid content concentration thereof might be 5 weight %. Thus obtained diluted composition was coated on one main surface of a polyethylene terephthalate (PET) substrate film 11 (produced by MITSUBISHI PLASTICS, INC.; product name: DAIA FOIL) with a thickness of 100 μm to be dried. Next, the diluted composition was cured by the irradiation of ultraviolet rays to form a hard coat layer 12 with a thickness of 700 nm. The substrate film 11 formed on the hard coat layer 12 was wound around to make a roll of the substrate film 11.

### [Formation of Optical Adjustment Layer]

An optical adjustment layer 13 (and a transparent conductor layer 14 to be described later) was formed by use of a roll-to-roll sputtering apparatus. The roll of the substrate film 11 formed on the hard coat layer 12 was placed in a supply portion of a sputtering apparatus and was kept in a vacuum state of 1×10⁻⁴ Pa or less for 15 hours. Subsequently, the substrate film 11 was unreeled from the supply portion to wind the substrate film 11 around a layer forming roll to deposit the optical adjustment layer 13 by the sputtering method. Specifically, a layer forming chamber was set to be in an argon gas atmosphere of 0.2 Pa and power with a power density of 3.5 W/cm² was applied while introducing oxygen gas by impedance control to form an optical adjustment layer 13 (silicon dioxide SiO₂) with a thickness of 15 nm by sputtering a silicon (Si) target (produced by Sumitomo Metal Mining Co., Ltd.).

### [Formation of Transparent Conductor Layer]

Subsequent to the formation of the optical adjustment layer 13, a transparent conductor layer 14 was deposited. The substrate film 11 where the optical adjustment layer 13 was formed was wound around the layer forming roll to form the transparent conductor layer 14 with a thickness of 20 nm by the sputtering method. At this time, the pressure ratio between argon gas Ar:oxygen gas O₂ was 99:1 and all gas pressure was in a sputtering atmosphere with 0.3 Pa and power with a power density of 1.0 W/cm² was applied. As a result, an indium tin oxide target composed of a sintered body containing 10 weight % of tin oxide and 90 weight % of indium oxide was sputtered to form the transparent conductor layer 14. Subsequently, the substrate film 11 was wound on a housing portion to complete a roll of the transparent conductive film 10.

### Example 2

A transparent conductive film 10 in Example 2 was produced in the same manner as in Example 1 except that the hard coat layer 12 had a thickness of 300 nm and the optical adjustment layer 13 had a thickness of 12 nm. The thickness of the optical adjustment layer 13 was 4.0% of the thickness of the hard coat layer 12.

### Example 3

A transparent conductive film 10 in Example 3 was produced in the same manner as in Example 1 except that the hard coat layer 12 had a thickness of 300 nm and the optical adjustment layer 13 had a thickness of 30 nm. The thickness of the optical adjustment layer 13 was 10.0% of the thickness of the hard coat layer 12.

### Comparative Example 1

A transparent conductive film in Comparative Example 1 was produced in the same manner as in Example 1 except that the hard coat layer had a thickness of 1,200 nm and the optical adjustment layer had a thickness of 12 nm. The thickness of the optical adjustment layer was 1.0% of the thickness of the hard coat layer.

### Comparative Example 2

A transparent conductive film in Comparative Example 2 was produced in the same manner as in Example 1 except that the hard coat layer had a thickness of 1,600 nm and the optical adjustment layer had a thickness of 12 nm. The thickness of the optical adjustment layer was 0.75% of the thickness of the hard coat layer.

### Comparative Example 3

A transparent conductive film in Comparative Example 3 was produced in the same manner as in Example 1 except that the hard coat layer had a thickness of 200 nm and the optical adjustment layer had a thickness of 12 nm. The thickness of the optical adjustment layer was 6.0% of the thickness of the hard coat layer.

Table 1 indicates each configuration and each characteristics of the transparent conductive films of the present invention in Examples 1 to 3 and Comparative Examples 1 to 3.

TABLE 1

| | | | | | Comparative | Comparative | Comparative |
|---|---|---|---|---|---|---|---|
| | | Example 1 | Example 2 | Example 3 | Example 1 | Example 2 | Example 3 |
| Layer | Transparent | 20 | 20 | 20 | 20 | 20 | 20 |
| configuration | conductor layer | | | | | | |
| (layer | (ITO) (nm) | | | | | | |
| thickness) | Optical | 15 | 12 | 30 | 12 | 12 | 12 |
| | adjustment layer | | | | | | |
| | (SiO₂) (nm) | | | | | | |
| | Hard coat layer | 700 | 300 | 300 | 1,200 | 1,600 | 200 |
| | (Acrylic ZrO₂) | | | | | | |
| | (nm) | | | | | | |
| | Substrate film | 100 | 100 | 100 | 100 | 100 | 100 |
| | (PET) (μm) | | | | | | |

| | | | | | | |
|---|---|---|---|---|---|---|
| Thickness ratio of optical | 2.1 | 4.0 | 10.0 | 1.0 | 0.75 | 6.0 |
| adjustment layer/hard | | | | | | |
| coat layer (%) | | | | | | |
| Crystallization of transparent | Completed | Completed | Completed | Not | Not | Completed |
| conductor layer | | | | completed | completed | |
| 140° C. for 30 minutes | | | | | | |
| Scratch resistance | Good | Good | Good | Good | Good | Bad |
| Overall evaluation | Good | Good | Good | Bad | Bad | Bad |

### [Crystallization of Transparent Conductor Layer]

Crystallization of the transparent conductor layer is preferably performed by heating at 140° C. for 30 minutes from a point of productivity. The transparent conductor layers in Examples 1 to 3 had no problems with productivity because crystallization had been completed by heating at 140° C. for 30 minutes (“Completed”). The transparent conductor layers in Comparative Examples 1 and 2 had problems with productivity because crystallization had not been completed by heating at 140° C. for 30 minutes (“Not completed”). The reason why the transparent conductor layers in Comparative Examples 1 and 2 are slow in crystallization was that the thickness of the optical adjustment layer was less than 2% of the thickness of the hard coat layer and outgas released from the hard coat layer entered the transparent conductor layer without sufficient blocking with the optical adjustment layer, thus resulting in inhibition of crystallization. The transparent conductor layer in Comparative Example 3 had no problems with crystallization because its crystallization had been completed by heating at 140° C. for 30 minutes (There were, however, problems with scratch resistance in Comparative Example 3).

### [Scratch Resistance]

The transparent conductive films in Examples 1 to 3 and Comparative Examples 1 and 2 had no problems with scratch resistance (“Good”). The transparent conductive film in Comparative Example 3 had low scratch resistance, which can cause a problem (“Bad”). The reason why the transparent conductive film in Comparative Example 3 had insufficient scratch resistance was that the thickness of the hard coat layer was less than 250 nm.

### [Overall Evaluation]

While overall evaluation in view of crystallization speed and scratch resistance of the transparent conductor layer was excellent in Examples 1 to 3 (“Good”), the overall evaluation was judged as poor (“Bad”) in Comparative Examples 1 to 3.

### [Measuring Method]

### [Thickness]

The cross-section of a transparent conductive film was observed by use of a transmission electron microscope (manufactured by Hitachi, Ltd.; product name: HF-2000) to measure each thickness of the optical adjustment layer and the transparent conductor layer.

### [Crystallization]

When the surface resistance value after heating at 140° C. for 30 minutes was 1.1 time or less as many as the surface resistance value after heating at 140° C. for 90 minutes, crystallization was judged as completed. In accordance with JIS K7194, a surface resistance value was measured by use of a four-terminal method.

### [Scratch Resistance]

The transparent conductive film that had been heated at 140° C. for 90 minutes was cut in the form of a rectangle of 5 cm×11 cm. A silver paste was applied to both end parts of 5 mm on the long edge side of the rectangle, and was naturally dried for 48 hours. A side of the transparent conductive film opposite to the transparent conductor layer was attached to a glass plate with a pressure sensitive adhesive to obtain a sample for evaluation of scratch resistance. At a central position (a position of 2.5 cm) on the short edge side of the sample for evaluation of scratch resistance, the surface of the transparent conductor layer in the sample for evaluation of scratch resistance was rubbed over a length of 10 cm in a long edge side direction under the conditions below by use of a decuplet-type pen testing machine (manufactured by MTM Co., Ltd.).

A resistance value (R0) of the sample for evaluation of scratch resistance before rubbing, and a resistance value (R20) of the sample for evaluation of scratch resistance after rubbing were measured by placing a tester on the silver paste part on both end parts at a central position (a position of 5.5 cm) on the long edge side of the sample for evaluation of scratch resistance, and the resistance change ratio (R20/R0) was determined to evaluate scratch resistance. A sample having a resistance change ratio of 1.5 or less was rated “excellent scratch resistance” (“Good”), and a sample having a resistance change ratio of over 1.5 was rated “poor scratch resistance” (“Bad”).
Scratcher: ANTICON GOLD (manufactured by CONTEC CO., LTD.)
Load: 127 g/cm²
Scratch rate: 13 cm/second (7.8 m/minute)
Scratch number: 20 (10 rounds)

### INDUSTRIAL APPLICABILITY

While uses of the transparent conductive film of the present invention are not limited, in particular, the transparent conductive film is suitably used for a touch panel.

### DESCRIPTION OF REFERENCE NUMERALS

10, 20, 30: transparent conductive film; 11: substrate film; 12: hard coat layer; 13: optical adjustment layer; 14: transparent conductor layer; 15: antistripping layer; 16: functional layer; 17: inorganic fine particles

1. A transparent conductive film comprising:
a transparent substrate film;
a hard coat layer;
an optical adjustment layer; and
a transparent conductor layer,
wherein at least the hard coat layer, the optical adjustment layer, and the transparent conductor layer are laminated on the transparent substrate film in this order,
the transparent conductor layer includes indium,
the hard coat layer has a thickness of 250 nm to 2,000 nm, and
the thickness of the optical adjustment layer is 2% to 10% of the thickness of the hard coat layer.

2. The transparent conductive film according to claim 1, wherein the optical adjustment layer includes a metal oxide.

3. The transparent conductive film according to claim 2, wherein the metal oxide includes silicon dioxide (SiO₂).

4. The transparent conductive film according to claim 1, wherein the hard coat layer includes any one of zirconium oxide ZrO₂, silicon dioxide SiO₂, titanium oxide TiO₂, tin oxide SnO₂, and aluminum oxide Al₂O₃ or at least two kinds of these inorganic fine particles.

5. The transparent conductive film according to claim 1, wherein the hard coat layer has a refractive index of 1.60 to 1.70.

6. The transparent conductive film according to claim 1, further comprising an antistripping layer formed between the hard coat layer and the optical adjustment layer.

7. The transparent conductive film according to claim 6, wherein the antistripping layer includes a non-stoichiometric inorganic compound.

8. The transparent conductive film according to claim 7, wherein the antistripping layer includes silicon atoms.

9. The transparent conductive film according to claim 8, wherein the antistripping layer includes a silicon compound.

10. The transparent conductive film according to claim 9, wherein the antistripping layer includes a silicon oxide.

11. The transparent conductive film according to claim 8, wherein the antistripping layer has an area wherein bond energy of a Si2p bond is 98.0 eV or more to less than 103.0 eV.

12. The transparent conductive film according to claim 6, wherein the antistripping layer has a thickness of 1.5 nm to 8 nm.

13. The transparent conductive film according to claim 1, further comprising a functional layer formed on the other main surface of the substrate film opposite to the transparent conductor layer.

14. The transparent conductive film according to claim 13, wherein the functional layer is composed of an anti-blocking hard coat layer.

15. The transparent conductive film according to claim 2, wherein the hard coat layer includes any one of zirconium oxide ZrO₂, silicon dioxide SiO₂, titanium oxide TiO₂, tin oxide SnO₂, and aluminum oxide Al₂O₃ or at least two kinds of these inorganic fine particles.

16. The transparent conductive film according to claim 2, wherein the hard coat layer has a refractive index of 1.60 to 1.70.

17. The transparent conductive film according to claim 2, further comprising an antistripping layer formed between the hard coat layer and the optical adjustment layer.

18. The transparent conductive film according to claim 2, further comprising a functional layer formed on the other main surface of the substrate film opposite to the transparent conductor layer.

19. The transparent conductive film according to claim 17, wherein the antistripping layer includes a non-stoichiometric inorganic compound.

20. The transparent conductive film according to claim 19, wherein the antistripping layer includes silicon atoms.

21. The transparent conductive film according to claim 20, wherein the antistripping layer includes a silicon compound.

22. The transparent conductive film according to claim 21, wherein the antistripping layer includes a silicon oxide.

23. The transparent conductive film according to claim 20, wherein the antistripping layer has an area wherein bond energy of a Si2p bond is 98.0 eV or more to less than 103.0 eV.

24. The transparent conductive film according to claim 17, wherein the antistripping layer has a thickness of 1.5 nm to 8 nm.
